(19) United States
(12) Patent Application Publication
(10) Pub. No.: US 2013/0161597 A1
(43) Pub. Date: Jun. 27, 2013

(54) METHOD OF INCORPORATING A BLACK PHOTO STRIPE OVER PARYLENE LAYER

(71) Applicant: EMAGIN CORPORATION, Hopewell Junction, NJ (US)

(72) Inventor: SHARON L. CONKLIN, STAATSBURG, NY (US)

(73) Assignee: EMAGIN CORPORATION, Hopewell Junction, NY (US)

(21) Appl. No.: 13/721,261

(22) Filed: Dec. 20, 2012

Related U.S. Application Data
(60) Provisional application No. 61/578,380, filed on Dec. 21, 2011.

(51) Int. Cl. H01L 33/58

(52) U.S. Cl. CPC H01L 33/58
USPC 257/40; 438/29

(57) ABSTRACT

A method of incorporating a structurally integrated black photo stripe over an OLED based light blocking means by sandwiching the black photo stripe between two layers of polymeric layers, above the OLED stack, seal and RGB color filter layer.

### CROSS-REFERENCE TO RELATED APPLICATION

This application claims the benefit of provisional patent application Ser. No. 61/578,380 filed in the United States Patent and Trademark Office on Dec. 21, 2011.

### BACKGROUND OF THE INVENTION

1. Field of the Invention

This invention relates generally to organic light-emitting diodes (OLEDs), and more particularly to a method of incorporating a structurally integrated black photo stripe over the OLED based sensor stripe for uniquely eliminating scattered light produced from the sensor stripe during testing, diagnostics and functioning of the display.

2. Description of the Related Art

The newest generation of chip and display designs incorporates a side sensor stripe therein. It is customary for the sensor stripe to be arranged vertical to the active area and built into the foundry design. The stripe is a column of pixels that light up during testing, diagnostics, and functioning of the display.

The peripheral light emitted by the sensor stripe is outside of the active display area and not desired by the customer. The present invention seeks to eliminate the presence of this undesirable scattered light by covering it up using a photolithographic align, expose, and develop process referred to as black photo stripe. The process utilizes a photosensitive black resist material.

Unfortunately, incorporating the black photo stripe process with the standard red, green, blue (RGB) photolithography processing has adverse outcomes and effects.

The current standard process of record for providing color filter over OLED, as shown in FIG. 1, is by first applying RGB stripes as individual photolithography steps over the 0.5 micron layer 16 (5000 angstroms) of parylene, seal 18 and OLED layers 20. A top layer 12 of parylene, of 1.0 micron thickness, is arranged over the RGB color filter stack 14.

Two primary methods attempted to incorporate the black photo stripe with the display architecture. The first method is to put the black photo stripe on the parylene surface layer 16 first, followed by the RGB color stripes. However, the results were not optimal and caused problems with the red, green, blue color expose and develop. Specifically, the frame design of the black photo stripe caused a lip (height) around the edge of the display that measured approximately 1 micron. The color material of the RGB does not develop out properly around this lip and causes tearing, cracking and lifting of the RGB color lines along the perimeter of the display.

The second method is to put the black photo stripe directly over the RGB color lines. This proves unsuccessful as well. The black resist used for the photo stripe requires a developer with a different surfactant and chemistry that is incompatible with the current RGB material. This results in lifting areas of the RGB color stripes already in place. Also, the pigmentation of the black material makes it harder to develop and wash off from on top of the RGB, such that when black residuals are not removed, it compromises the color integrity of the display.

While these solutions may be suitable for the particular purpose employed, or for general use, they would not be as suitable for the purposes of the present invention as disclosed hereafter.

It is, therefore, a primary object of the present invention to incorporate a black photo stripe into display architecture without causing infraction to the RGB color process from either directly under or directly over it.

It is another object of the present invention to provide a process for sandwiching the black photo stripe layer between parylene layers such that the thin film post organic stack architecture remains the same while the display device provides an increase in yield.

It is another object of the present invention to provide a process that ensures there are no black residuals remaining on the surface of the RGB color stripes.

It is another object of the present invention to provide a process that decreases cycle time without having to utilize prior art methods of metal liftoff sensor stripe cover-ups.

### BRIEF SUMMARY OF THE INVENTION

In accordance with one aspect of the present invention, a photolithographic process incorporates a method for blocking light within an OLED display. Preferably, the light blocking method is a sensor stripe. The process comprises sandwiching a photosensitive black resist material between two polymeric layers arranged above an OLED display stack. Ideally, the polymeric layers are parylene layers are of equal thickness.

In accordance with an additional embodiment, an organic light-emitting diode display comprises an OLED stack, multiple polymeric layers, preferably parylene, a red green blue color filter layer, and a sensor means. Here, the sensor means eliminates scattered light by providing a black photo stripe sandwiched between two parylene layers within the OLED display. It is preferable to have the parylene layers of equal thickness.

In accordance with an additional embodiment, an organic light-emitting diode display includes an OLED stack and a seal layer arranged on the OLED stack. Next, a first polymeric layer is arranged on the seal layer and then red, green and blue color filter subpixels are arranged on the first polymeric layer. Thereafter, a second polymeric layer is arranged on the color filter subpixels. Finally, a black photo stripe layer is arranged on the second polymeric layer and a third polymeric layer is included. Preferably, the first, second and third polymeric layers, ideally parylene layers, are of equal thickness and the black photo stripe layer is a photosensitive black resist material.

### BRIEF DESCRIPTION OF THE SEVERAL VIEWS OF THE DRAWINGS

To these and to such other objects that may hereinafter appear, the present invention relates to incorporating a black photo stripe into the display architecture without causing infraction to the RGB color process as described in detail in the following specification and recited in the annexed claims, taken together with the accompanying drawings, in which like numerals refer to like parts in which:

FIG. 1 is a schematic diagram of the display architecture of the prior art, wherein a customary process of color filter over OLED is implemented; and

FIG. 2 is a schematic diagram of the display architecture of the present invention, wherein a black photo stripe is incorporated into the display architecture by sandwiching the black photo stripe layer between polymeric layers.

To the accomplishment of the above and related objects the invention may be embodied in the form illustrated in the accompanying drawings. Attention is called to the fact, however, that the drawings are illustrative only. Variations are contemplated as being part of the invention, limited only by the scope of the claims.

### DETAILED DESCRIPTION OF THE INVENTION

The present invention is directed to an improved process for incorporating a black photo stripe into display architecture without causing infraction to the RGB color process from either directly under or directly over it.

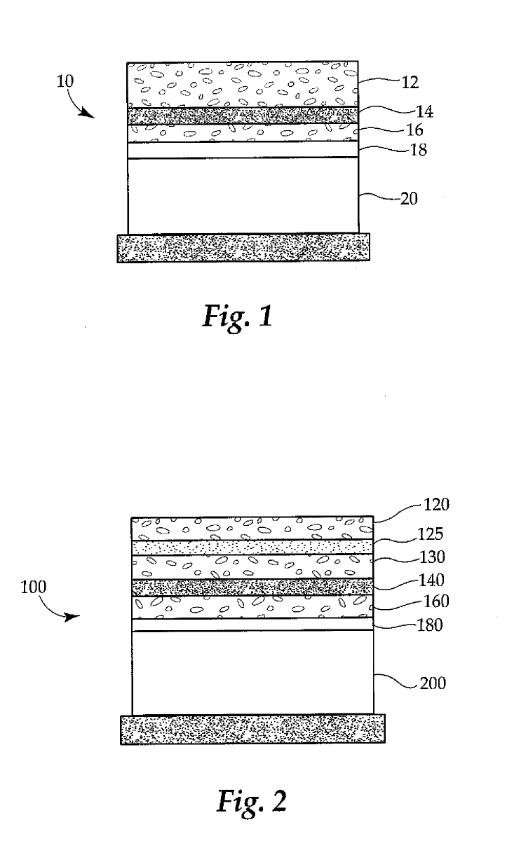

FIG. 1 illustrates the standard prior art display architecture 10 when incorporating color filter over OLED. This prior art display architecture 10 includes first applying RGB stripes as individual photolithography steps over the 0.5 micron layer 16 (5000 angstroms) of parylene, seal layer 18 and OLED layers 20. A top layer 12 of parylene, of 1.0 micron thickness, is arranged over the RGB color filter stack 14.

As discussed supra, two methods were attempted to incorporate the black photo stripe within the prior art display architecture. However, both methods posed serious obstacles including tearing, lifting and cracking of the RGB color lines.

FIG. 2 illustrates the display architecture 100 of the present invention, which implements an advantageous process for sandwiching the black photo stripe layer 125 between equal thickness polymeric or dielectric layers 120, 130, such that the thin film post organic stack architecture 200 remains the same while the display device provides an increase in yield. Preferably, the polymeric or dielectric layers 120, 130 are parylene layers.

Specifically, the black photo stripe 125 is sandwiched between two layers of parylene, namely a top layer 120 and a bottom layer 130. The standard top layer 12 of parylene as shown in FIG. 1, is of 1.0 micron in thickness. In the present embodiment the top layer of parylene is halved into two equal 0.5 micron layers, including the third layer 120 and the second layer 130. The parylene layers 120, 130 do not have to be of equal thickness and can be anywhere from approximately 1,000 to 50,000 Angstroms.

The RGB color layer 140 is processed normally according to customary standards in the art above the conventional OLED layers 200, seal layer 180, and first parylene layer 160, of 0.5 micron thickness.

After the RGB color layer 140 is applied, the second parylene layer 130, of 0.5 micron thickness, is applied above the RGB color layer 140 for protecting the colors of the display architecture 100. The second layer 130 of parylene ensures there are no black residuals remaining on the surface of the RGB color stripe layer 140.

Next, the black photo stripe layer 125 is applied, exposed, and developed onto the second parylene layer 130, which is compatible to material used for the present process. After the black photo stripe layer 125 is applied, a third layer 120, of 0.5 micron parylene, is applied directly on top thereof. Thus, the display architecture 100 of the present invention includes the black photo stripe layer 125 sandwiched between the second and third layers 130, 120 of equal thickness parylene.

In conclusion, herein is presented a process for integrating a black photo stripe into the display architecture. The invention is illustrated by example in the drawing figures, and throughout the written description. It should be understood that numerous variations are possible, while adhering to the inventive concept. Such variations are contemplated as being a part of the present invention. While only a limited number of preferred embodiments of the present invention have been disclosed for purposes of illustration, it is obvious that many modifications and variations could be made thereto. It is intended to cover all of those modifications and variations, which fall within the scope of the present invention as defined by the following claims.

I claim:

1. A photolithographic process for incorporating a light blocking means within an OLED display, the process comprises a means for sandwiching a photosensitive black resist material between two polymeric layers arranged above an OLED display stack.

2. The photolithographic process of claim 1, wherein the light blocking means is a sensor stripe.

3. The photolithographic process of claim 1, wherein said polymeric layers are parylene layers.

4. The photolithographic process of claim 1, wherein said polymeric layers are of equal thickness.

5. An organic light-emitting diode display comprising, an OLED stack, multiple polymeric layers, a red green blue color filter layer, and a sensor means for eliminating scattered light by providing a black photo stripe sandwiched between two polymeric layers within the OLED display.

6. The organic light-emitting diode display of claim 5, wherein said polymeric layers are parylene layers.

7. The organic light-emitting diode display of claim 5, wherein said polymeric layers are of equal thickness.

8. An organic light-emitting diode display comprising:
an OLED stack;
a seal layer arranged on said OLED stack;
a first polymeric layer arranged on said seal layer;
red, green and blue color filter subpixels arranged on said first polymeric layer;
a second polymeric layer arranged on said color filter subpixels;
a black photo stripe layer arranged on said second polymeric layer; and
a third polymeric layer.

9. The organic light-emitting diode display of claim 8, wherein the first, second and third polymeric layers are parylene layers.

10. The organic light-emitting diode display of claim 8, wherein the first, second and third polymeric layers are of equal thickness.

11. The organic light-emitting diode display of claim 8, wherein the black photo stripe layer is a photosensitive black resist material.
